(19) United States
(12) Patent Application Publication
(10) Pub. No.: US 2024/0363765 A1
(43) Pub. Date: Oct. 31, 2024

(54) FLASH MEMORY CELL WITH TUNABLE TUNNEL DIELECTRIC CAPACITANCE

(71) Applicant: Taiwan Semiconductor Manufacturing Company, Ltd., Hsinchu (TW)

(72) Inventors: Gerben Doornbos, Kessel-Lo (BE); Georgios Vellianitis, Heverlee (BE); Marcus Johannes Henricus Van Dal, Linden (BE); Yu-Ming Lin, Hsinchu City (TW); Oreste Madia, Bsruxelles (BE)

(21) Appl. No.: 18/306,488

(22) Filed: Apr. 25, 2023

(51) Int. Cl. H01L 29/788; H01L 21/28; H01L 29/423; H01L 29/66

(52) U.S. Cl. CPC H01L 29/7883; H01L 29/40114; H01L 29/42324; H01L 29/66825

(57) ABSTRACT

Some embodiments relate to an integrated device, including a control gate over a substrate, the control gate having a first length; a tunnel dielectric on the control gate; a floating gate having a second length on the tunnel dielectric, the tunnel dielectric separating the control gate and the floating gate; a blocking dielectric on the floating gate; a channel on the blocking dielectric, the blocking dielectric separating the channel and the floating gate; and source/drain terminals on the channel, wherein the first length of the control gate is less than the second length of the floating gate.

### BACKGROUND

Many modern day electronic devices contain electronic memory. Electronic memory may be volatile memory or non-volatile memory. Non-volatile memory is able to retain its stored data in the absence of power, whereas volatile memory loses its stored data when power is disconnected. Flash memory is one type of non-volatile memory. Flash memory utilizes the tunneling of electrons into and out of a floating gate in order to change the threshold voltage of the flash memory cell. The tunneling of electrons is induced by applying a program voltage or an erase voltage to the control gate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a flash memory cell with a back end of line (BEOL) layout and an inverted tunneling configuration.

FIGS. 2A-2B illustrate a cross-sectional view and a top layout view of a BEOL flash memory array.

FIGS. 3A-3B illustrate cross-sectional views of the operation of a BEOL flash memory array utilizing a tunnel dielectric between the control gate and the floating gate.

FIG. 4A-4G illustrate a plurality of cross-sectional views of some embodiments of a BEOL flash memory cell and array.

FIG. 5 illustrates a cross-sectional view of some embodiments of an integrated circuit comprising a BEOL flash memory array and a front end of line (FEOL) transistor array.

FIGS. 6, 7A, 7B, 7C. 7D, 7E, 8, 9, 10, 11, 12, 13, and 14 illustrate a plurality of cross-sectional views of some embodiments of a method of forming a BEOL flash memory array.

FIG. 15 illustrates a methodology in flowchart format that illustrates some embodiments of the present concept.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A flash memory cell includes a control gate and source/drain terminals, with a floating gate arranged between the control gate and the source/drain terminals. During operation, a program voltage or erase voltage applied to the control gate sets a state of the flash memory cell to either an “0” state or a “1” state. In conventional flash memory cells, to set the flash memory cell to the “0” state, the program voltage is applied to the control gate. The application of the program voltage pulls electrons into the floating gate from the channel, resulting in an increased threshold voltage relative to the “1” state. The increased threshold voltage is due to an electric field of the electrons in the floating gate repelling electrons in the channel. To set the flash memory cell to the “1” state, the erase voltage is applied to the control gate. The application of the erase voltage pushes the electrons out of the floating gate and back into the channel, resulting in a decreased threshold voltage relative to the “0” state. The program voltage and the erase voltage of the flash memory cell depend on the capacitance of both a blocking dielectric separating the control gate and the floating gate and a tunnel dielectric separating the floating gate and the channel. The thickness, length, width, and material of the blocking dielectric and tunnel dielectric affect the capacitance.

In conventional flash memory arrays, the flash memory cells and logic devices are formed in the same front end of line (FEOL) process on a substrate. As different configurations of logic devices have been developed, such as fin field-effect transistors (FinFETS) and gate-all-around field-effect transistors (GAA-FETS), it is increasingly difficult to utilize the processes used to make logic devices to also fabricate flash memory cells.

Furthermore, the program voltage and the erase voltage of a flash memory cell depends on a voltage drop over the tunnel oxide. Increasing the voltage drop relative to the voltage applied at the control gate increases an efficiency of the flash memory cell by lowering a magnitude of the program voltage and the erase voltage. A ratio of the voltage drop to the voltage applied at the control gate is dependent on both a capacitance of the blocking dielectric between the control gate and the floating gate, and a capacitance of the tunnel dielectric between the floating gate and the channel. To increase the ratio, a small tunnel dielectric capacitance relative to the blocking dielectric capacitance may be desirable.

The capacitance of the blocking dielectric and the tunnel dielectric are dependent on their respective thicknesses, lengths, and widths. However, the thickness of the tunnel dielectric is optimized for the transfer of electrons between the channel and the floating gate. Further, the thickness of the blocking dielectric is optimized to block the transfer of electrons between the control gate and the floating gate, so altering the thicknesses to change the capacitance is not desirable. The lengths and widths of the tunnel dielectric and blocking dielectric are also difficult to manipulate, as they are often determined by a single gate etch. Therefore, a process that includes the capacity to tune the length and width of the tunnel dielectric independent of the length and width of the blocking dielectric is desirable.

Therefore, a method of forming flash memory devices that may be used in conjunction with the various designs for logic devices while also being able to tune a length and width of the tunnel dielectric is desirable. The present disclosure provides techniques to form a back end of line (BEOL) flash memory cell utilizing an inverted tunneling configuration. By forming the flash memory cell using BEOL-compatible processes, the provided techniques result in flash memory arrays that are suitable for embedding into circuits having logic devices formed to have different configurations (e.g., such as fin field-effect transistors (FinFETS), gate-all-around field-effect transistors (GAA-FETS), etc.). Additionally, the BEOL-compatible processes of forming a flash memory cell utilizing an inverted tunneling configuration etch the tunnel dielectric and blocking dielectric separately, which results in the dimensions of the tunnel dielectric being independent of the dimensions of the blocking dielectric. Independently determining the dimensions of the tunnel dielectric and blocking dielectric leads to an easily tunable capacitance ratio in the final design.

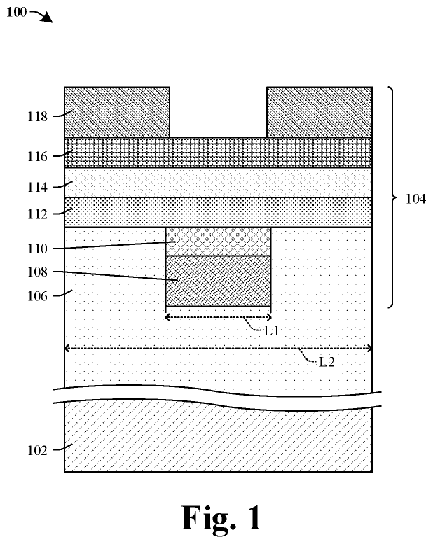

FIG. 1 illustrates a cross-sectional view 100 of some embodiments of a flash memory cell with a back end of line (BEOL) layout.

A flash memory cell 104 is above a substrate 102. A plurality of interlayer dielectric (ILD) layers 106 separate the flash memory cell 104 from the substrate 102. The flash memory cell 104 comprises a control gate 108. A tunnel dielectric 110 overlies the control gate 108, separating the control gate 108 from a floating gate 112. A blocking dielectric 114 overlies the floating gate 112, separating the floating gate from a channel 116. Source/drain terminals 118 overlie the channel 116 and are separated by a non-zero distance directly over the tunnel dielectric 110.

In some embodiments, the tunnel dielectric 110 or the control gate 108 has a first length L1 and the blocking dielectric 114 has a second length L2 that is greater than the first length L1. The difference between the first length L1 and the second length L2 is one factor that causes a capacitance of the tunnel dielectric 110 to be less than a capacitance of the blocking dielectric 114. The lower capacitance of the tunnel dielectric 110 increases a voltage drop across the tunnel dielectric 110 relative to a voltage applied at the control gate 108. The voltage drop across the tunnel dielectric 110 directly affects a tunneling current in the tunnel dielectric 110. Therefore, changing the length L1 of the tunnel dielectric 110 allows for tuning the capacitance of the tunnel dielectric 110, which further affects the voltage drop and tunneling current within the tunnel dielectric 110. As the voltage drop is relative to the voltage applied at the control gate 108, changing the length L1 also affects the minimum voltage that may be used to induce the tunneling current in the tunnel dielectric 110. In some additional embodiments, the capacitance of the tunnel dielectric 110 may also be tuned by having different width of the tunnel dielectric and blocking dielectric, by having different thicknesses of the tunnel dielectric and the blocking dielectric, and/or by having different dielectric constants of the tunnel dielectric and the blocking dielectric.

Therefore, by changing the width, length, thickness, and/or dielectric constant of the tunnel dielectric and the blocking dielectric, a relatively low ratio of the tunnel dielectric capacitance relative to the blocking dielectric capacitance can be achieved. The relatively low ratio increases the voltage drop over the tunnel dielectric relative to the applied voltage. A higher ratio of voltage drop to applied voltage lowers the magnitude of a write voltage and an erase voltage applied at the control gate that may be used to set the state of the flash memory cell. A lower write voltage and erase voltage increases an efficiency of operation for the flash memory cell.

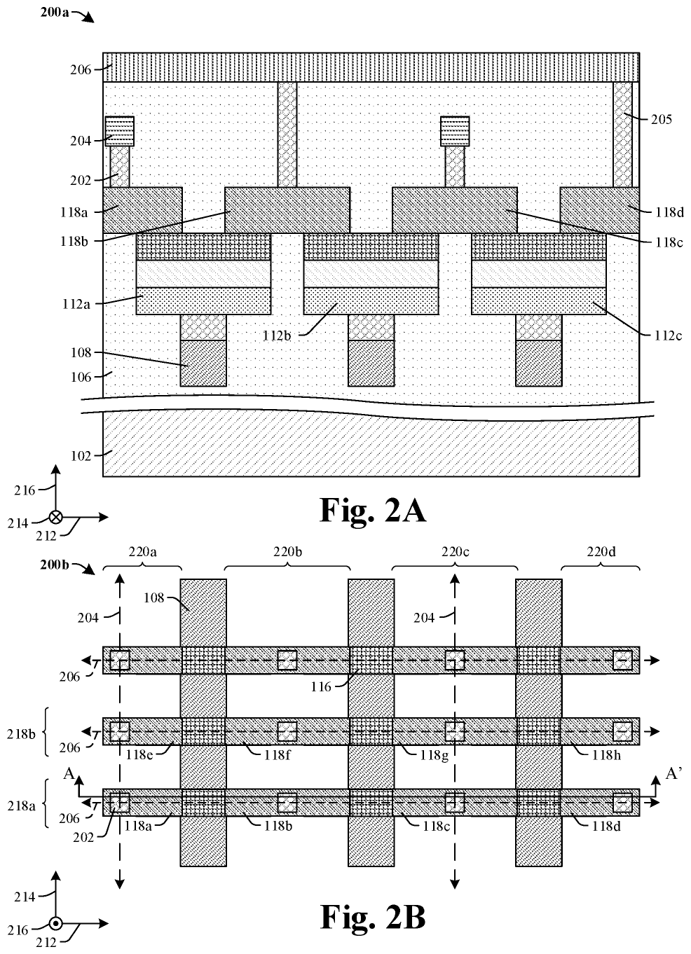

FIGS. 2A-2B illustrate a cross-sectional view 200a and a top layout view 200b of a BEOL flash memory array. The cross-sectional view 200a of FIG. 2A may, for example, be taken along line A-A′ in FIG. 2B. In the top layout view 200b of FIG. 2B, the plurality of ILD layers 106 are omitted for clarity.

As shown in the cross-sectional view 200a of FIG. 2A, the BEOL flash memory array comprises a plurality of flash memory devices arranged within a plurality of ILD layers 106 over a substrate 102. The plurality of flash memory devices are separated from one another by one or more ILD layers 106 along a first direction 212. A plurality of source/drain terminals are disposed on the plurality of flash memory devices. A plurality of interconnects 202-206 are disposed within an upper ILD structure disposed over the plurality of source/drain terminals.

In some embodiments, the plurality of interconnects may comprise a first plurality of vias 202 and a second plurality of vias 205. The first plurality of vias 202 extend from a first portion 118a, 118c of source/drain terminals 118a-118d to a plurality of second interconnect wires 204. The second plurality of vias 205 extend from a second portion 118b, 118d of the source/drain terminals 118a-118d to a plurality of first interconnect wires 206. The first portion 118a, 118c and the second portion 118b, 118d of source/drain terminals 118 are interleaved in a first direction 212 along of the flash memory array. The source/drain terminals 118a-118d respectively overlie two of a plurality of floating gates 112a-112c. For example, a first source/drain terminal 118b overlies a first floating gate 112a and a second floating gate 112b, and a second source/drain terminal 118c overlies the second floating gate 112b and a third floating gate 112c. The plurality of first interconnect wires 206 extend in the first direction 212, and the plurality of second interconnect wires 204 extend in a second direction 214 perpendicular to the first direction 212. The first plurality of vias 202 and the second plurality of vias 205 extend from the source/drain terminals 118a-118d in a third direction 216 perpendicular to both the first direction 212 and the second direction 214.

As shown in the top layout view 200b of FIG. 2B, the control gate 108 extends in the second direction 214 parallel to the second interconnect wires 204 (represented by dotted lines). Source/drain terminals 118a-118h are arranged in a plurality of rows 218a-218b and columns 220a-220d. The source/drain terminals 118a-118h in columns 220a-220d with the first portion 118a, 118c of source/drain terminals are coupled to the plurality of second interconnect wires 204. That is, source/drain terminals 118a-118h that are in line with the first portion 118a, 118c of source/drain terminals 118a-118h in the second direction 214 are also coupled to the plurality of second interconnect wires 204. Further, source/drain terminals 118a-118h that are in line with the second portion 118b, 118d of the source/drain terminals 118a-118h in the second direction 214 are coupled to the plurality of first interconnect wires 206 (represented by dotted lines).

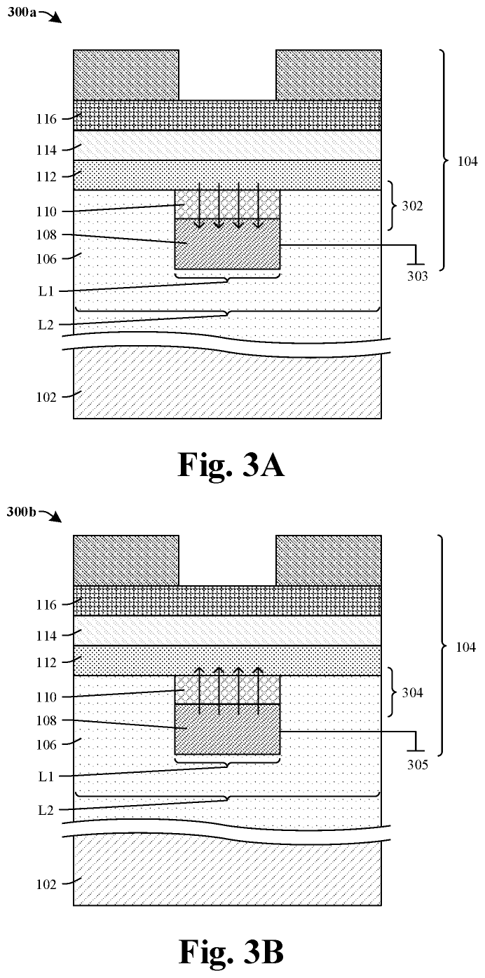

FIGS. 3A-3B illustrate cross-sectional views 300a, 300b of the operation of a BEOL flash memory cell utilizing a tunnel dielectric between the control gate and the floating gate. FIGS. 3A and 3B are now described concurrently.

The flash memory cell 104 stores 1 bit of information by being in a “0” state or a “1” state. Supplying the program voltage (e.g., in a “program” operation) or the erase voltage (e.g., in an “erase” operation) at the control gate 108 may change the state of the flash memory cell from a “0” state to a “1” state or from a “1” state to a “0” state, respectively. The state of the flash memory cell 104 is changed by altering a charge stored in the floating gate 112. The charge is changed by electrons tunneling into and out of the floating gate 112 through the tunnel dielectric 110. The charge alters the threshold voltage of the flash memory cell, which changes the current which is detected through the channel 116 during a “read” operation. The blocking dielectric 114 prevents electrons from traveling between the floating gate 112 and the channel 116.

For example, as shown in the cross-sectional view 300a of FIG. 3A, a program voltage 303 is supplied to the control gate 108. The program voltage 303 is a positive voltage that is greater than a first minimum value to draw electrons 302 out of the floating gate 112, through the tunnel dielectric 110, and into the control gate 108. The first minimum value depends on the voltage drop over the tunnel dielectric 110, which depends on the capacitance of the tunnel dielectric 110, and the capacitance of the blocking dielectric 114. The removal of electrons 302 from the floating gate 112 results in the floating gate 112 having a more positive charge, which lowers the threshold voltage of the flash memory cell 104. When a read voltage is subsequently provided to the control gate 108 during a “read” operation, the read voltage is greater than the threshold voltage of the flash memory cell 104, resulting in a high current flow through the channel 116.

As shown in the cross-sectional view 300b of FIG. 3B, an erase voltage 305 is supplied to the control gate 108. The erase voltage 305 is a negative voltage that is less than a second maximum value to push electrons 304 out of the control gate 108, through the tunnel dielectric 110, and into the floating gate 112. The second maximum value depends on the voltage drop over the tunnel dielectric 110, which depends on the capacitance of the tunnel dielectric 110, and the capacitance of the blocking dielectric 114. The addition of electrons 304 to the floating gate 112 results in the floating gate 112 having a more negative charge, which raises the threshold voltage of the flash memory cell 104. When a read voltage is subsequently provided to the control gate 108 during a “read” operation, the read voltage is less than the threshold voltage of the flash memory cell 104, resulting in a current flow through the channel 116 which is less than the current flow through the channel 116 described in relation to FIG. 3A. The read voltage is below the first minimum voltage, and above the second maximum voltage, so that during the read operation there are no electrons traveling between the floating gate and the control gate, and the state of the flash memory cell is not disturbed.

The transfer of electrons 302, 304 through the tunnel dielectric 110 between the control gate 108 and the floating gate 112 results in a flash memory cell 104 with a more flexible design than flash memory cells which transfer electrons between the channel 116 and the floating gate 112. As shown previously, the length L1 (and therefore capacitance) of the control gate 108 and tunnel dielectric 110 is independent of the length L2 of the floating gate 112, the blocking dielectric 114 and the channel 116, and the flash memory cell 104 may have a lower program voltage 303 when the capacitance of the tunnel dielectric 110 is smaller than the capacitance of the blocking dielectric 114. Therefore, the capacitance of the tunnel dielectric 110 can be controlled, leading to a flexible design for the flash memory cell 104 that can be configured to operate at a larger range of input voltages.

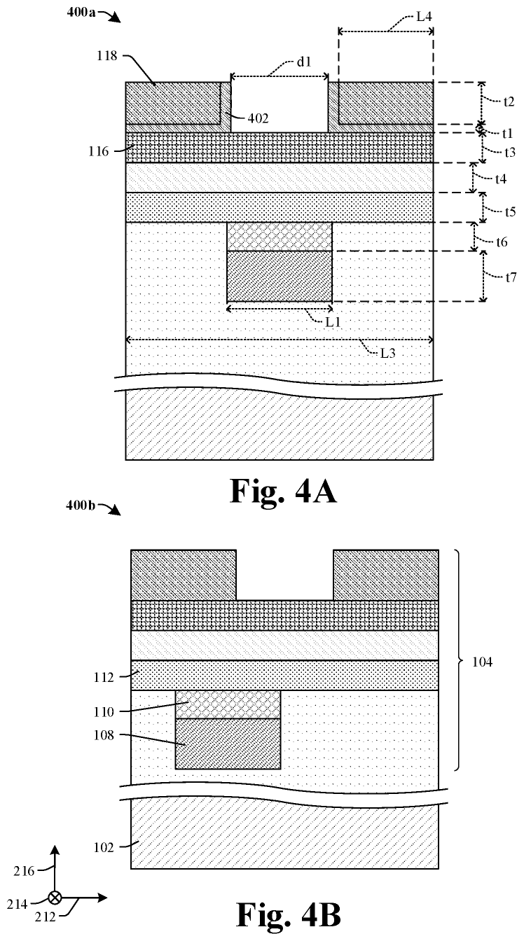

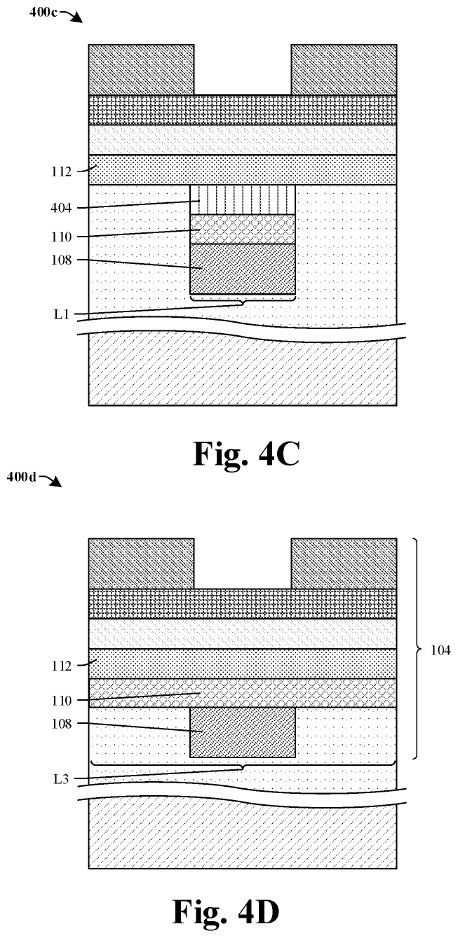

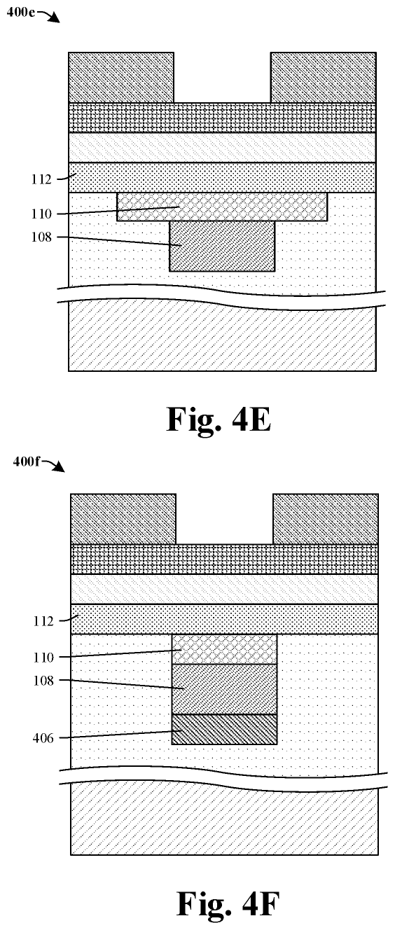

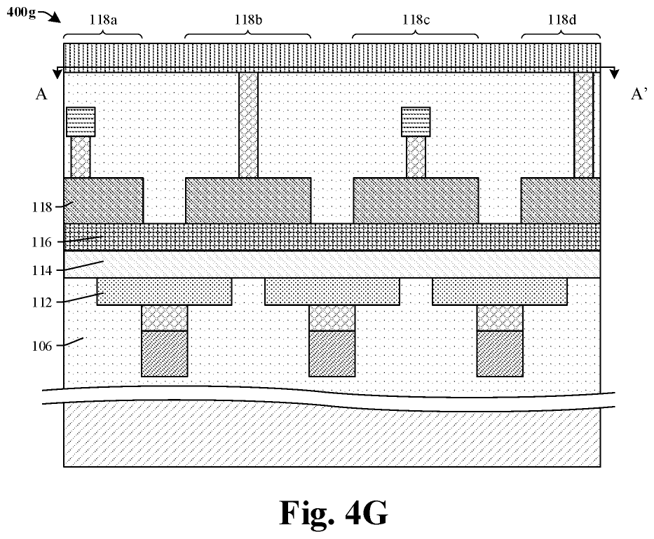

FIG. 4A-4G illustrate a plurality of cross sectional views of some alternative embodiments of the BEOL flash memory cell and the BEOL flash memory array.

As shown in the cross-sectional view 400a of FIG. 4A, in some embodiments, a conductive liner 402 is formed between the source/drain terminals 118 and the channel 116. In some embodiments, the conductive liner 402 is or comprises, for example, indium gallium zinc oxide (InGaZnO), indium oxide (InO), indium tin oxide (InSnO), indium zinc oxide (InZnO), indium tungsten oxide (InWO), or the like.

In some embodiments, the conductive liner 402 has a thickness t1 approximately between 3 and 10 nanometers, approximately between 1 and 5 nanometers, approximately between 4 and 15 nanometers, or within another suitable range. In some embodiments, the source/drain terminals 118 have a thickness t2 approximately between 10 and 40 nanometers, approximately between 5 and 30 nanometers, approximately between 15 and 50 nanometers, or within another suitable range. In some embodiments, the channel 116 has a thickness t3 approximately between 4 and 20 nanometers, approximately between 2 and 16 nanometers, approximately between 6 and 24 nanometers, or within another suitable range. In some embodiments, the blocking dielectric 114 has a thickness t4 approximately between 4 and 10 nanometers, approximately between 2 and 8 nanometers, approximately between 6 and 12 nanometers, or within another suitable range. In some embodiments, the floating gate 112 has a thickness t5 approximately between 4 and 20 nanometers, approximately between 2 and 16 nanometers, approximately between 6 and 24 nanometers, or within another suitable range. In some embodiments, the tunnel dielectric 110 has a thickness t6 approximately between 4 and 10 nanometers, approximately between 2 and 8 nanometers, approximately between 6 and 12 nanometers, or within another suitable range. In some embodiments, the control gate 108 has a thickness t7 approximately between 10 and 40 nanometers, approximately between 5 and 30 nanometers, approximately between 15 and 50 nanometers, or within another suitable range.

In some embodiments, the control gate 108 has the first length L1 approximately between 20 and 120 nanometers, approximately between 10 and 100 nanometers, approximately between 30 and 140 nanometers, or within another suitable range. In some embodiments, the floating gate 112 has a third length L3 approximately between 60 and 120 nanometers, approximately between 50 and 100 nanometers, approximately between 70 and 140 nanometers, or within another suitable range. In some embodiments, the second length L2 (see FIG. 1) is equal to the third length L3. In some embodiments, the source/drain terminals 118 have a fourth length L4 approximately between 20 and 40 nanometers, approximately between 15 and 30 nanometers, approximately between 25 and 50 nanometers, or within another suitable range. In some embodiments, the source/drain terminals 118 are spaced by a distance dl approximately between 20 and 40 nanometers, approximately between 15 and 30 nanometers, approximately between 25 and 50 nanometers, or within another suitable range.

As shown in the cross-sectional view 400b of FIG. 4B, in some embodiments, the control gate 108 and the tunnel dielectric 110 are offset from a center of the floating gate 112 in the first direction 212 and/or the second direction 214. An offset control gate 108 does not compromise the functionality of the flash memory cell 104. Therefore, the control gate 108 may be offset from the center of the floating gate 112 to resolve design rule issues and/or align with other components of layers beneath the control gate 108.

As shown in the cross-sectional view 400c of FIG. 4C, in some embodiments, a secondary floating gate 404 is directly above the tunnel dielectric 110. In some embodiments, the secondary floating gate 404 comprises a same material as the floating gate 112. In other embodiments, the secondary floating gate 404 is or comprises, for example, a conductive material different from the material of the floating gate 112. The secondary floating gate 112 has a length equal to the first length L1 of the tunnel dielectric 110, and is etched during a same etching process as the tunnel dielectric 110. The secondary floating gate 404 may be included to protect the tunnel dielectric 110 during a subsequent planarization process.

As shown in the cross-sectional view 400d of FIG. 4D, in some embodiments, the tunnel dielectric 110 may have a length equal to a third length L3 of the floating gate 112. The process of forming the tunnel dielectric 110 may be performed after the control gate 108 has been etched and planarized. The tunnel dielectric 110 being formed after the planarization of the control gate 108 is another method that avoids performing a planarization process on the tunnel dielectric 110. Having the planarization process end on the tunnel dielectric 110 may cause the tunnel dielectric 110 to be damaged and cause a failure of the flash memory cell 104.

As shown in the cross-sectional view 400e of FIG. 4E, in some embodiments, the tunnel dielectric 110 may have a length between the length of the control gate 108 and the length of the floating gate 112.

As shown in the cross-sectional view 400f of FIG. 4F, in some embodiments, a metal layer 406 is beneath the control gate 108. In further embodiments, the control gate 108 is and/or comprises a heavily doped (e.g., to a dopant concentration greater than 10²⁰ atoms per cubic centimeter) silicon.

As shown in the cross-sectional view 400g of FIG. 4G, in some embodiments, the blocking dielectric 114 and the channel 116 extend continuously between the source/drain terminals 118a-118d and over a plurality of discrete floating gates 112. In such embodiments, the blocking dielectric 114 continuously extends over both an upper surface of the floating gate 112 and an upper surface of one of the plurality of ILD layers 106. This configuration may remove one or more etching steps from the method of fabrication, leading to a more cost-efficient and faster process.

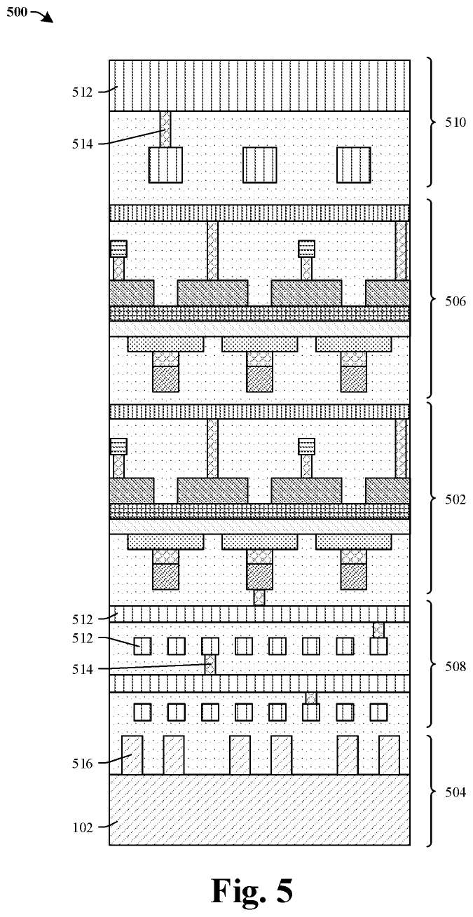

FIG. 5 illustrates a cross-sectional view 500 of some embodiments of an integrated circuit structure comprising a BEOL flash memory array and an FEOL transistor array.

The integrated circuit structure comprises a first flash memory array 502 that overlies FEOL devices 504 on the substrate 102. In some embodiments, a second flash memory array 506 extends over the first flash memory array 502. In this way, any number of flash memory arrays may be embedded in the integrated circuit using BEOL-compatible processes. In some embodiments, lower BEOL interconnect layers 508 separate the first flash memory array 502 from the FEOL devices 504. In some embodiments, upper BEOL interconnect layers 510 may overlie the first flash memory array 502. The lower BEOL interconnect layers 508 and the upper BEOL interconnect layers 510 both comprise a plurality of wires 512 and a plurality of vias 514 coupled to the plurality of wires 512. In some embodiments, the plurality of vias 514 are coupled to the first flash memory array 502. The FEOL devices 504 comprise a plurality of logic devices 516 on the substrate 102. The plurality of logic devices 516 may be or comprise metal-oxide-semiconductor field-effect transistors (MOSFETs), fin field-effect transistors (FinFETs), gate-all-around field-effect transistors (GAA FETs), nanosheet field-effect transistors, the like, or any combination of the foregoing. The use of BEOL processes to form flash memory arrays results in a more flexible integrated circuit design that may utilize ongoing developments in transistor technology.

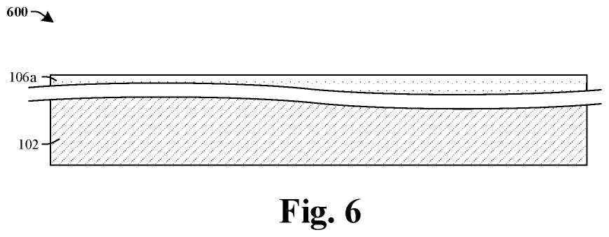

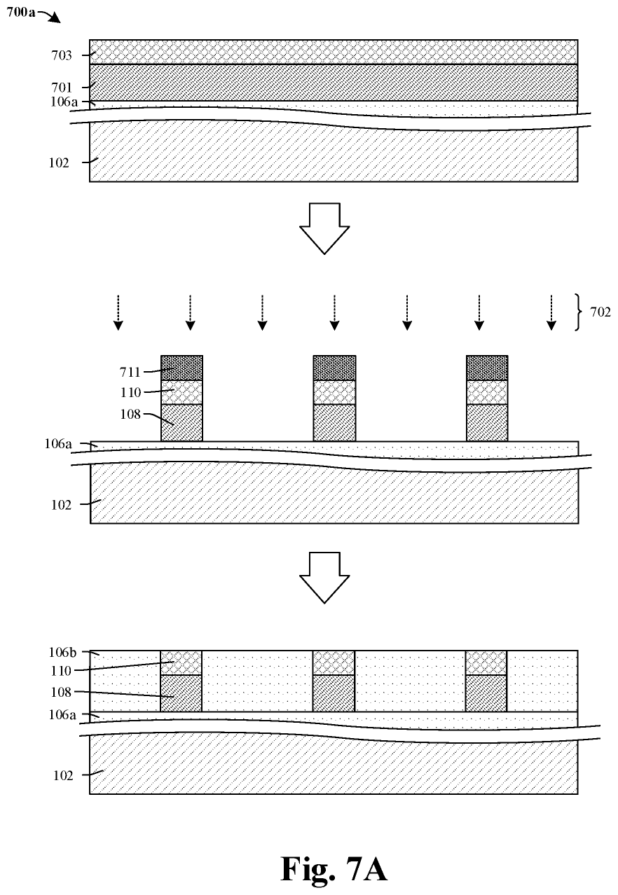

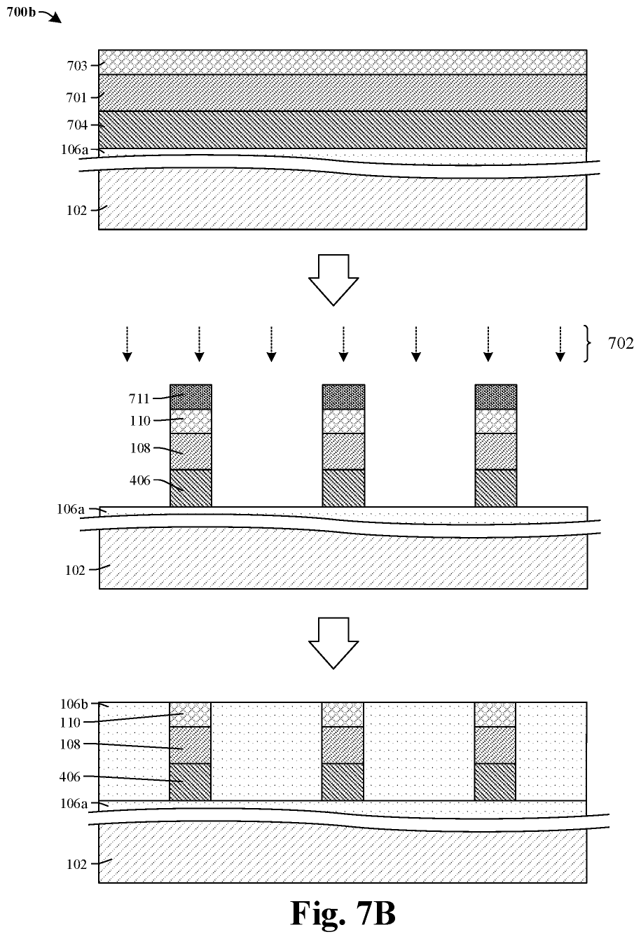

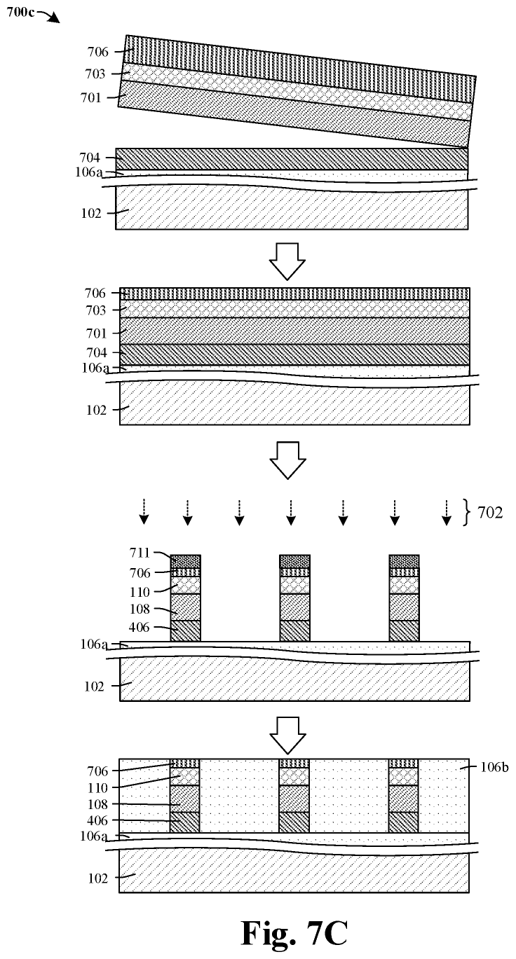

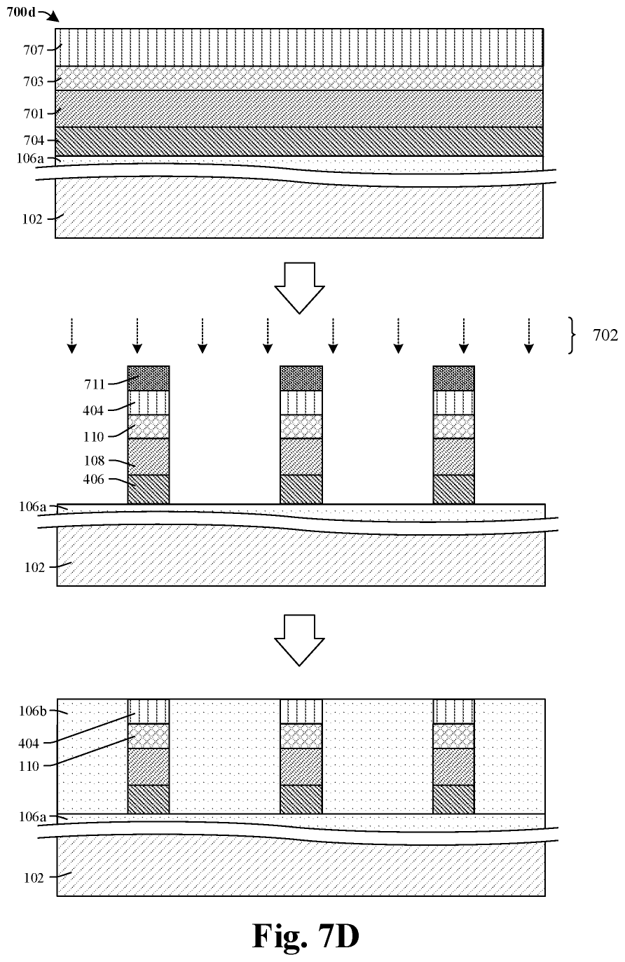

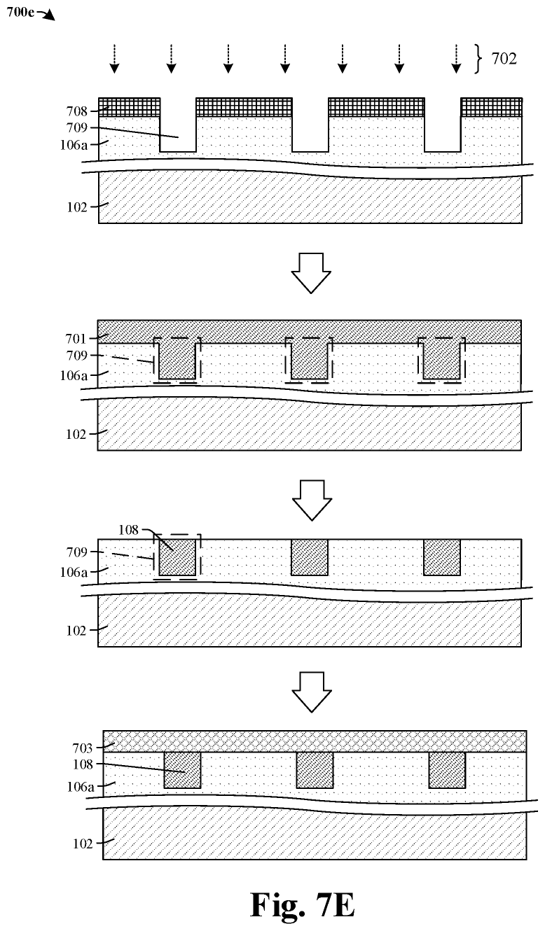

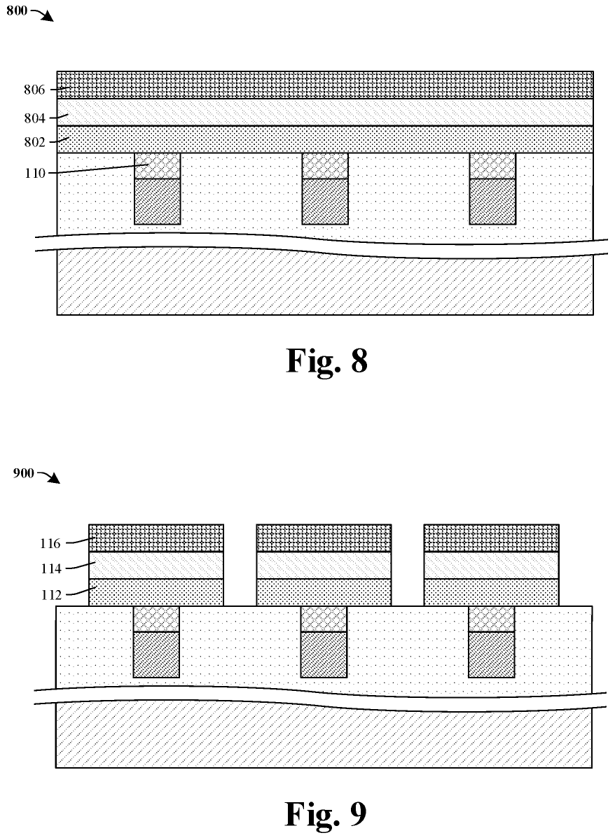

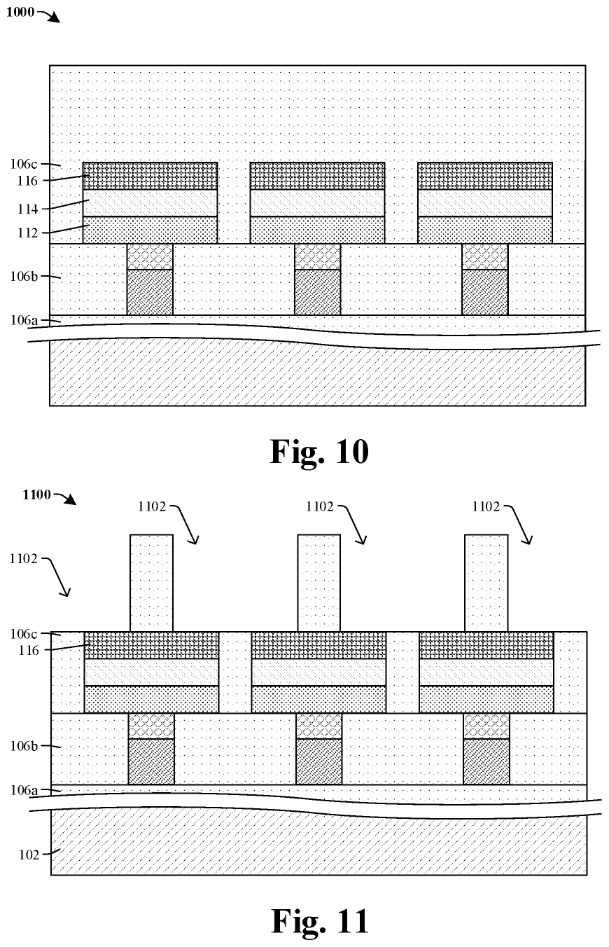

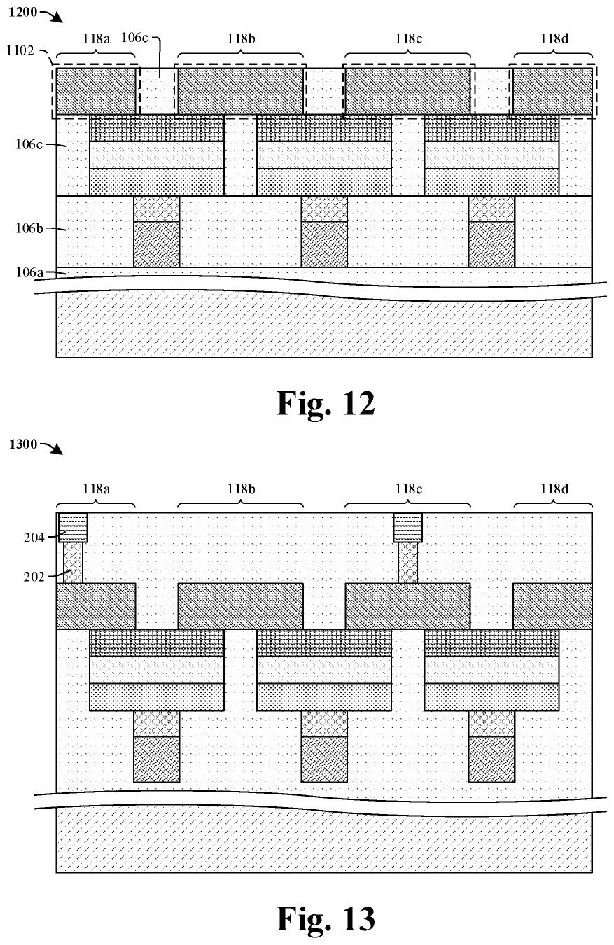

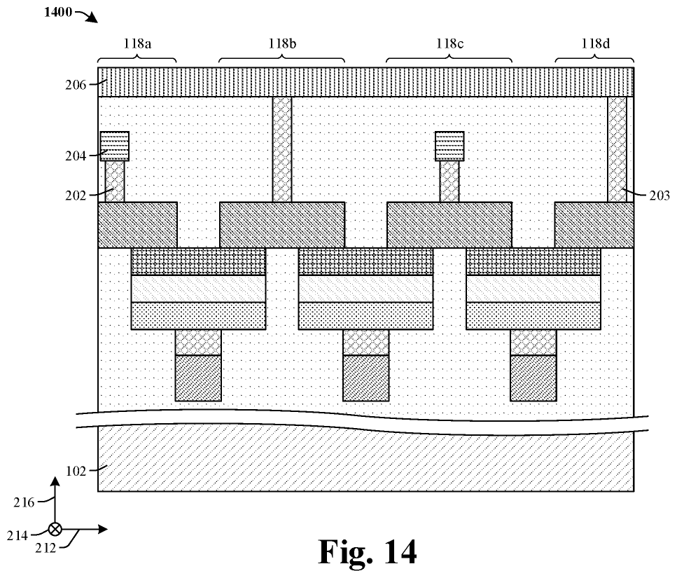

With reference to FIGS. 6, 7A, 7B, 7C. 7D, 7E, 8, 9, 10, 11, 12, 13, and 14, cross-sectional views of some embodiments of a BEOL flash memory array are provided. Although FIGS. 6, 7A, 7B, 7C, 7D, 7E, 8, 9, 10, 11, 12, 13, and 14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 6 illustrates a cross-sectional view 600 of a first ILD layer 106a formed over a substrate 102. In some embodiments, the first ILD layer 106a comprises silicon dioxide (SiO₂) or the like. The substrate 102 may be any type of substrate. In some embodiments, the substrate 102 comprises a semiconductor body, e.g., silicon, SiGe, silicon-on-insulator (SOI), or the like. The substrate 102 may be a semiconductor wafer, one or more dies on a wafer, or any other type of semiconductor body and/or epitaxial layers. In some embodiments, the first ILD layer 106a may surround one or more lower interconnects (e.g., conductive contacts, interconnect vias, and/or interconnect wires). In some embodiments, the substrate 102 comprises a FEOL layer of devices.

FIGS. 7A, 7B, 7C, 7D, and 7E illustrate cross-sectional views 700a, 700b, 700c. 700d, 700c of various methods of forming the control gate 108 and the tunnel dielectric 110.

In some embodiments, as shown in FIG. 7A, a control gate layer 701 is formed over the first ILD layer 106a, and a tunnel dielectric layer 703 is formed on the control gate layer 701. In some embodiments, the control gate layer 701 is formed using chemical vapor deposition (CVD), physical vapor deposition (PVD), atomic layer deposition (ALD), sputtering, electrochemical plating, electroless plating, some other suitable deposition process, or a combination of the foregoing. In some embodiments, the tunnel dielectric layer 703 is formed using CVD, PVD, ALD, some other suitable deposition process, or a combination of the foregoing. In some embodiments, the control gate layer 701 is or comprises, for example, one of titanium nitride (TiN), tantalum nitride (TaN), tungsten (W), copper (Cu), ruthenium (Ru), cobalt (Co), heavily doped silicon, a combination of the foregoing, or the like. In some embodiments, the tunnel dielectric layer 703 is or comprises, for example, one of silicon dioxide (SiO₂), silicon nitride (Si₃N₄), silicon oxynitride (SiON), a combination of the foregoing, or the like.

The control gate layer 701 and the tunnel dielectric layer 703 are then patterned using a first etching process 702 to respectively form an array of a control gate 108 and a tunnel dielectric 110. The tunnel dielectric layer 703 and the control gate layer 701 are patterned according to a first mask 711 which is formed over the tunnel dielectric layer 703. The first etching process 702 may, for example, use a dry etching technique suitable for etching through the tunnel dielectric layer 703 and the control gate layer 701. In various embodiments, the first etching process 702 may comprise a plasma etch with tetrafluoromethane (CF₄), sulfur hexafluoride (SF₆), nitrogen trifluoride (NF₃), or the like. In further embodiments, when the control gate layer 701 is a metal, the first etching process 702 may comprise and additional plasma etch with carbon tetrachloride (CCl₄), boron trichloride (BCl₃), or the like. The tunnel dielectric layer 703 and the control gate layer 701 are patterned into the control gate 108 and the tunnel dielectric 110. The first mask 711 is then removed.

After the first etching process 702 and the removal of the first mask 711, a second ILD layer 106b is deposited around the control gate 108 and the tunnel dielectric 110. A planarization process (e.g., a chemical-mechanical planarization (CMP) process) is then performed, removing portions of the second ILD layer 106b that are above the tunnel dielectric 110. The second ILD layer 106b covers upper surfaces of the first ILD layer 106a and sidewalls of the control gate 108 and tunnel dielectric 110.

In other embodiments, as shown in FIG. 7B, the control gate layer 701 comprises silicon, and is formed over a conformal metal layer 704. In some embodiments, the control gate layer 701 is formed using CVD, PVD, ALD, some other suitable deposition process, or a combination of the foregoing. In some embodiments, the deposition of the control gate layer 701 is followed by an implantation process to implant dopants into the control gate layer 701. The dopants have a doping concentration greater than 10²⁰ atoms per cubic centimeter. In some embodiments, the tunnel dielectric layer 703 is formed by annealing the control gate layer 701 on an ambient containing oxygen (O₂) or water (H₂O), growing the tunnel dielectric layer 703 comprising silicon dioxide. In other embodiments, the tunnel dielectric layer 703 may be formed using CVD, PVD, ALD, or the like.

A first etching process 702 is then performed to pattern the tunnel dielectric layer 703, the control gate layer 701, and the conformal metal layer 704 to respectively form a tunnel dielectric 110, a control gate 108, and a metal layer 406. The first etching process 702 patterns the tunnel dielectric layer 703, the control gate layer 701, and the conformal metal layer 704 according to the first mask 711, which is subsequently removed. After the removal of the first mask 711, the second ILD layer 106b is formed by depositing dielectric material and removing portions of the dielectric material above an upper surface of the tunnel dielectric 110 using a planarization process.

In yet other embodiments, as shown in FIG. 7C, the control gate layer 701 and the tunnel dielectric layer 703 are formed on a sacrificial wafer 706 and then bonded to the conformal metal layer 704 or the ILD layer 106. The sacrificial wafer 706 is then wholly or partially removed. In some embodiments, the sacrificial wafer 706 is removed using a planarization process (e.g., a chemical mechanical planarization (CMP) process, an etch back process) or some other suitable removal process. This method forms the tunnel dielectric layer 703 and the control gate layer 701 on a separate wafer, resulting in less strain on a thermal budget of the integrated circuit.

A first etching process 702 is then performed to pattern the tunnel dielectric layer 703, the control gate layer 701, and the conformal metal layer 704 to respectively form a tunnel dielectric 110, a control gate 108, and a metal layer 406. The first etching process 702 patterns the tunnel dielectric layer 703, the control gate layer 701, and the conformal metal layer 704 according to the first mask 711, which is subsequently removed. After the removal of the first mask 711, the second ILD layer 106b is formed by depositing dielectric material and removing portions of the dielectric material above an upper surface of the tunnel dielectric 110 using a planarization process. In some embodiments, the planarization process removes portions of the dielectric material above an upper surface of the sacrificial wafer 706.

In yet other embodiments, as shown in FIG. 7D, a secondary floating gate layer 707 is formed over the tunnel dielectric layer 703. The secondary floating gate layer 707 is or comprises, for example, titanium nitride (TiN), tantalum nitride (TaN), a titanium aluminum alloy (TiAl), heavily doped polysilicon, a combination of the foregoing, or the like.

A first etching process 702 is then performed to pattern the secondary floating gate layer 707, the tunnel dielectric layer 703, the control gate layer 701, and the conformal metal layer 704 to respectively form a secondary floating gate 404, a tunnel dielectric 110, a control gate 108, and a metal layer 406. The first etching process 702 patterns the secondary floating gate layer 707, the tunnel dielectric layer 703, the control gate layer 701, and the conformal metal layer 704 according to the first mask 711, which is subsequently removed. After the removal of the first mask 711, the second ILD layer 106b is formed by depositing dielectric material and removing portions of the dielectric material above an upper surface of the secondary floating gate 404 using a planarization process. The secondary floating gate 404 covers the tunnel dielectric 110 during the planarization process. This results in less damage being done to the tunnel dielectric 110, which may extend the lifetime of the flash memory cell 104.

In yet other embodiments, as shown in FIG. 7E, the control gate layer 701 is formed on the first ILD layer 106a using a damascene process. The first etching process 702 is used to form a control gate opening 709 in the first ILD layer 106a according to a second mask 708. A control gate layer 701 is then deposited into the control gate opening 709. After the control gate layer 701 is deposited, a planarization process (e.g., a CMP process) is performed, removing portions of the control gate layer 701 over the upper surface of the first ILD layer 106a. The tunnel dielectric layer 703 is then deposited over the control gate 108. In some embodiments, the tunnel dielectric layer 703 is not subsequently etched into the tunnel dielectric 110 (see FIG. 1).

The method continues according to the embodiment of FIG. 7A. It will be appreciated that in other embodiments (not shown) the method may alternatively continue from the embodiments of FIGS. 7B-7E. As shown in the cross-sectional view 800 of FIG. 8, a floating gate layer 802, a blocking layer 804, and a channel layer 806 are formed over the tunnel dielectric 110. In some embodiments, the floating gate layer 802 is formed using CVD, PVD, ALD, sputtering, electrochemical plating, electroless plating, some other suitable deposition process, or a combination of the foregoing. In some embodiments, the blocking layer 804 and the channel layer 806 are formed using CVD, PVD, ALD, some other suitable deposition process, or a combination of the foregoing. In some embodiments, the floating gate layer 802 is or comprises, for example, titanium nitride (TiN), tantalum nitride (TaN), a titanium aluminum alloy (TiAl), heavily doped polysilicon, a combination of the foregoing, or the like. In some embodiments, the blocking layer 804 is or comprises, for example, hafnium oxide (HFO₂), aluminum oxide (Al₂O₃), hafnium zirconium oxide (HfZrO), a combination of the foregoing, or the like. In some embodiments, the channel layer 806 is or comprises, for example, InGaZnO (IGZO), InO, InSnO (ITO), InZnO, InWO, polycrystalline silicon, silicon-germanium (SiGe), a combination of the foregoing, or the like.

As shown in the cross-sectional view 900 of FIG. 9, the floating gate layer 802 (see FIG. 8), the blocking layer 804 (see FIG. 8), and the channel layer 806 (see FIG. 8) are etched to form the floating gate 112, the blocking dielectric 114, and the channel 116, respectively. In some embodiments, the floating gate layer 802 is etched before the forming of the blocking layer 804 and the channel layer 806, so the blocking layer 804 and the channel layer 806 extend continuously over the floating gate 112 without being subsequently etched.

As shown in the cross-sectional view 1000 of FIG. 10, a third ILD layer 106c is formed over the floating gate 112, the blocking dielectric 114, and the channel 116. In some embodiments, the third ILD layer 106c is formed using CVD, PVD, ALD, some other suitable deposition process, or a combination of the foregoing.

As shown in the cross-sectional view 1100 of FIG. 11, the third ILD layer 106c is etched, forming a plurality of source/drain openings 1102. The plurality of source/drain openings 1102 extend to the channel 116. In some embodiments, the third ILD layer 106c may be etched using one or more of, for example, a dry etching process, a reactive ion etching (RIE) process, some other etching process, or a combination of the foregoing.

As shown in the cross-sectional view 1200 of FIG. 12, the source/drain terminals 118a-118d are formed in the source/drain openings 1102 (shown in phantom). The source/drain terminals 118a-118d are formed by depositing a source/drain material in the source/drain openings 1102, then performing a planarization process (e.g., a CMP process) to remove portions of the source/drain material above the third ILD layer 106c. In some embodiments, the source/drain terminals 118a-118d are or comprise, for example, titanium nitride (TiN), tungsten (W), copper (Cu), ruthenium (Ru), cobalt (Co), nickel (Ni), nickel silicide (NiSi), a combination of the foregoing, or the like. As shown in FIG. 4A, the source/drain terminals may comprise a conductive liner 402.

As shown in the cross-sectional view 1300 of FIG. 13, the first plurality of vias 202 and the second interconnect wires 204 are formed over the source/drain terminals 118a-118d. In some embodiments, the first plurality of vias 202 and the second interconnect wires 204 are formed using single damascene processes. In other embodiments, the first plurality of vias 202 and the second interconnect wires 204 are formed using a dual-damascene process. The first plurality of vias 202 couple the second interconnect wires 204 to a first portion 118a, 118c of the source/drain terminals 118a-118d. In some embodiments, the first portion 118a, 118c of the source/drain terminals 118a-118d is an even-numbered or odd-numbered set of the source/drain terminals 118a-118d.

As shown in the cross-sectional view 1400 of FIG. 14, the second plurality of vias 203 and the plurality of first interconnect wires 206 are formed over the source/drain terminals 118a-118d. In some embodiments, the second plurality of vias 203 and the plurality of first interconnect wires 206 are formed using single damascene processes. In other embodiments, the second plurality of vias 203 and the plurality of first interconnect wires 206 are formed using a dual-damascene process. The second plurality of vias 203 couple the plurality of first interconnect wires 206 to a second portion 118b, 118d of the source/drain terminals 118a-118d. In some embodiments, the second portion 118b, 118d of the source/drain terminals 118a-118d is an even-numbered or odd-numbered set of the source/drain terminals 118a-118d. In some embodiments, source/drain terminals 118a-118d alternate between coupling to the second interconnect wires 204 and the plurality of first interconnect wires 206 in the first direction 212.

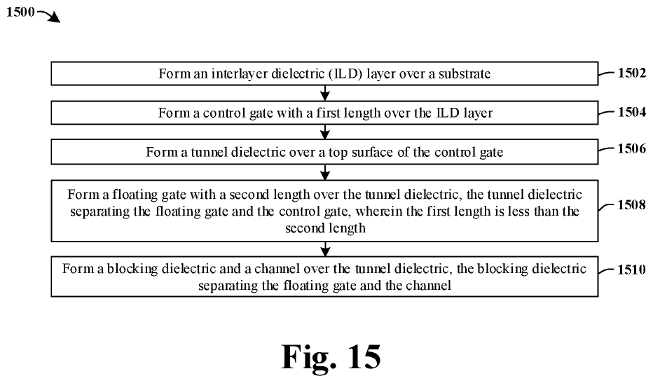

FIG. 15 illustrates a methodology 1500 of forming a BEOL flash memory cell in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1502, an interlayer dielectric (ILD) layer is formed over a substrate. See, for example, FIG. 6.

At 1504, a control gate with a first length is formed over the ILD layer. See, for example, FIGS. 7A, 7B, 7C, 7D, 7E.

At 1506, a tunnel dielectric is formed over a top surface of the control gate. See, for example, FIGS. 7A, 7B, 7C. 7D, 7E.

At 1508, a floating gate with a second length is formed over the tunnel dielectric, the tunnel dielectric separating the floating gate and the control gate, wherein the first length is less than the second length. See, for example, FIGS. 8-9.

At 1510, a blocking dielectric and a channel are formed over the tunnel dielectric, the blocking dielectric separating the floating gate and the channel. See, for example, FIGS. 8-9.

Therefore, the present disclosure relates to a method of forming a BEOL flash memory array with an inverted tunneling configuration.

Some embodiments relate to an integrated device, including a control gate over a substrate, the control gate having a first length; a tunnel dielectric on the control gate; a floating gate having a second length on the tunnel dielectric, the tunnel dielectric separating the control gate and the floating gate; a blocking dielectric on the floating gate; a channel on the blocking dielectric, the blocking dielectric separating the channel and the floating gate; and source/drain terminals on the channel, wherein the first length of the control gate is less than the second length of the floating gate.

Other embodiments relate to a flash memory cell, including a control gate in an interlayer dielectric (ILD), wherein the control gate is configured to apply a program voltage and an erase voltage to the flash memory cell; a floating gate extending over the control gate and configured to hold a charge determined by the most recent of the program voltage or erase voltage applied to the flash memory cell, wherein the charge alters a threshold voltage of the flash memory cell; and a tunnel dielectric extending between the floating gate and the control gate and configured to pass electrons between the floating gate and the control gate when the program voltage or the erase voltage is applied to the flash memory cell.

Yet other embodiments relate to a method of forming an integrated device, including forming a control gate with a first length over a substrate; forming a tunnel dielectric over a top surface of the control gate; forming a floating gate with a second length over the tunnel dielectric, the tunnel dielectric separating the floating gate and the control gate, wherein the first length is less than the second length; and forming a blocking dielectric and a channel over the tunnel dielectric, the blocking dielectric separating the floating gate and the channel.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a control gate over a substrate, the control gate having a first length;
a tunnel dielectric on the control gate;
a floating gate having a second length on the tunnel dielectric, the tunnel dielectric separating the control gate and the floating gate;
a blocking dielectric on the floating gate;
a channel on the blocking dielectric, the blocking dielectric separating the channel and the floating gate; and
source/drain terminals on the channel;
wherein the first length of the control gate is less than the second length of the floating gate.

2. The integrated device of claim 1, wherein the control gate and the source/drain terminals are spaced from the substrate by an interlayer dielectric (ILD) layer.

3. The integrated device of claim 1, further comprising:
a first interconnect wire coupled to a first portion of the source/drain terminals and extending in a first direction; and
a second interconnect wire coupled to a second portion of the source/drain terminals and extending in a second direction, wherein the control gate extends in the second direction perpendicular to the first interconnect wire.

4. The integrated device of claim 1, wherein the tunnel dielectric has a first dielectric constant and the blocking dielectric has a second dielectric constant greater than the first dielectric constant.

5. The integrated device of claim 1, further comprising a liner extending between the source/drain terminals and the channel.

6. The integrated device of claim 1, wherein the first length and the second length are measured in a first direction, and wherein the tunnel dielectric has a third length measured in the first direction that is less than the second length.

7. The integrated device of claim 6, wherein the floating gate has a first sidewall and a second sidewall opposite the first sidewall and separated in the first direction, and the tunnel dielectric and the control gate are closer to the first sidewall than the second sidewall.

8. The integrated device of claim 1, further comprising a second floating gate extending between the floating gate and the tunnel dielectric, wherein the second floating gate has the first length.

9. The integrated device of claim 8, wherein the blocking dielectric and the channel have the second length.

10. A flash memory cell, comprising:
a control gate in an interlayer dielectric (ILD) layer;
a floating gate extending over the control gate and configured to hold a charge determined by a program voltage or erase voltage applied to the control gate, wherein the charge alters a threshold voltage of the flash memory cell; and
a tunnel dielectric extending between the floating gate and the control gate and configured to pass electrons between the floating gate and the control gate when the program voltage or the erase voltage is applied, altering the charge of the flash memory cell.

11. The flash memory cell of claim 10, wherein the control gate has a first length measured in a first direction, and the floating gate has a second length measured in the first direction, and the second length is greater than the first length.

12. The flash memory cell of claim 11, wherein the tunnel dielectric has a third length measured in the first direction, wherein the third length is less than the second length and greater than the first length.

13. The flash memory cell of claim 10, further comprising a channel separated from the floating gate by a blocking dielectric, wherein the channel is configured to pass a current from a first source/drain terminal to a second source/drain terminal based on a voltage measured at the control gate and the charge held by the floating gate.

14. The flash memory cell of claim 13, wherein when the program voltage is applied to the flash memory cell by the control gate, the tunnel dielectric is configured to pass the electrons from the floating gate to the control gate, decreasing the threshold voltage of the flash memory cell.

15. The flash memory cell of claim 13, wherein when the erase voltage is applied to the flash memory cell by the control gate, the tunnel dielectric is configured to pass the electrons from the control gate to the floating gate, increasing the threshold voltage of the flash memory cell.

16. A method of forming an integrated device, comprising:
forming an interlayer dielectric (ILD) layer over a substrate;
forming a control gate with a first length over the ILD layer;
forming a tunnel dielectric over a top surface of the control gate;
forming a floating gate with a second length over the tunnel dielectric, the tunnel dielectric separating the floating gate and the control gate, wherein the first length is less than the second length; and
forming a blocking dielectric and a channel over the tunnel dielectric, the blocking dielectric separating the floating gate and the channel.

17. The method of claim 16, wherein forming the floating gate, the blocking dielectric, and the channel over the tunnel dielectric further comprises:
depositing a floating gate layer, a blocking layer, and a channel layer over the substrate and the tunnel dielectric; and
patterning the floating gate layer, the blocking layer, and the channel layer using one etching process to form the floating gate, the blocking dielectric, and the channel directly over the tunnel dielectric.

18. The method of claim 16, wherein forming the floating gate, the blocking dielectric, and the channel over the tunnel dielectric further comprises:
depositing a floating gate layer over the ILD layer and the tunnel dielectric;
patterning the floating gate layer to form the floating gate directly over the tunnel dielectric;
depositing a second ILD layer around and over the floating gate layer;
performing a planarization process on the second ILD layer; and
depositing the blocking dielectric and the channel over the second ILD layer and the floating gate.

19. The method of claim 16, wherein forming the control gate and the tunnel dielectric over the substrate further comprises:
forming a silicon layer over the ILD layer; and
performing an anneal to form a silicon dioxide layer on the silicon layer.

20. The method of claim 16, wherein forming the control gate and the tunnel dielectric over the substrate further comprises:
forming the tunnel dielectric and the control gate on a separate wafer;
bonding the separate wafer to the integrated device; and
removing the separate wafer, leaving the tunnel dielectric and control gate on the integrated device.
